(19) United States
(12) Patent Application Publication
(10) Pub. No.: US 2014/0262849 A1
(43) Pub. Date: Sep. 18, 2014

(54) ERGONOMIC IMPACT DAMAGE RESISTANCE PROTECTOR AND METHODS OF USE THEREOF

(71) Applicant: MAV IP LLC, Las Vegas, NV (US)

(72) Inventors: Alexander James Karp, San Diego, CA (US); Michael Anthony Ishibashi Chapp, East Lansing, MI (US); Victor Anh Chung, Escondido, CA (US)

(73) Assignee: MAV IP LLC, Las Vegas, NV (US)

(21) Appl. No.: 14/214,812

(22) Filed: Mar. 15, 2014

Related U.S. Application Data
(60) Provisional application No. 61/802,285, filed on Mar. 15, 2013.

(51) Int. Cl. H05K 5/00

(52) U.S. Cl. CPC H05K 5/0086
USPC 206/37; 29/428

(57) ABSTRACT

Provided herein are ergonomic impact damage resistant protector devices, and methods of use thereof. The protector devices are configured to be adapted to the edges, corners and/or boundary regions of an article having defined edges, boundaries and/or corners. Particularly, the disclosure is directed to impact damage resistant protector devices positioned substantially at boundaries, edges and corners of an article whereby the adaptation of the protector devices onto the article will effectively serve as a shock absorber and/or impact diffuser thereby preventing external impact forces from being transmitted internally to the article.

### RELATED APPLICATION

This is a regular U.S. application claiming priority to U.S. Provisional Application Ser. No. 61/802,285, entitled Fractionated Cover And Positioning Device That Provides Bump Protection For Sensitive Handheld Devices, filed Mar. 15, 2013, the contents of which are herein incorporated by reference as if set forth in their entirety.

### FIELD OF THE INVENTION

Present disclosure is directed to ergonomic impact damage resistant protector, and methods of use thereof. The protectors are configured to be adapted to the edges, corners and/or boundary regions of an article having defined edges, boundaries and/or corners. Particularly, the disclosure is directed to impact damage resistant protectors posited substantially at boundaries, edges and corners of a device whereby the adaptation of the protectors onto the devices will effectively serve as a shock absorber and/or impact diffuser thereby preventing external impact forces from being transmitted internally to the device.

### BACKGROUND

Various types of electronic devices currently exist for communications and entertainment purposes. These devices include various type of smart phones, tablet computers, video players, MP3 players and other types of communication devices such as walkie talkies, mobile phones, and other types of electronic devices. These devices often contain display screens, interactive touch screens, keyboards, push-button switches and other interactive controls. Furthermore, these devices often use specific surface coatings and textures, such as an oleophobic coating to reduce finger oils, to enhance or provide interactive features, such as non-visual tactile feedback. Furthermore, secondary devices, such as light sensors, waterproof cases, battery packs, microphones, audio amplifiers, are often attached to the primary device to enhance or provide additional features.

These devices, both the primary device and secondary device, are very widely used in residential, as well as office environments and carried by persons, such as in one's hand or in a garment pocket. These environments often contain hard flat surfaces such as concrete sidewalks and floors, asphalt parking lots, granite counters, wood-composite desks, and various other materials. These surfaces impose harsh conditions that typical electronic devices are not designed to accommodate. For example, damage can be done to a smartphone or attached light sensor, such as surface scratches or a cracked screen through rough handling or dropping.

It would therefore be advantageous to provide protection for these devices to be used in common residential and office environments. Furthermore, the interaction with surface coatings and surface textures and secondary attached devices should not be hindered by a protective case. Furthermore, the protective case should not interfere with transportation or typical storage, such as in a garment pocket.

Other devices require complete or near complete encapsulation to provide attachment to the electronic device and offer the shock protection. These other protective devices and methods offer limited shock protection must cover, partially or fully, the electronic device adding both volume and weight to the handheld device.

### SUMMARY OF THE INVENTION

The present invention overcomes the disadvantages and limitations of prior art by providing a fractionated (can be adapted individually as a single unit or adapted in a multiunit configuration) impact damage resistant protectors whereby the surfaces, interactive controls, and display screen may be viewed and manipulated without impeding the performance of the display, surface, and interactive controls while the device is protected by the protector.

An embodiment of the present invention may therefore comprise one or more protectors comprising shock absorbing elements wherein the shock absorbing elements are positioned to receive impacts which would otherwise strike the device, e.g. a handheld device. The shock absorbing elements may be located substantially on the edges, boundaries, and/or corners of the handheld device and may further comprise shock absorbing elements located near specific elements, such as a camera lens, of the handheld device. Once adapted onto the device, the specific combination of the composition configuration and the shape of the protectors design allow for advantageous dynamic motion of the protector unit during impact and thereby achieve optimal elastic compression and/or cushioning and impact force dissipation.

In one embodiment, the shock absorbing elements of the protector comprise a shock absorbing layer and an outer rigid layer. The shock absorbing layer has mechanical properties that absorb shocks and has sufficient elasticity to conform which allows a pressure sensitive adhesive to maintain fluid contact with the outer surface of the exemplary device, such as, for example, a handheld device, and allows a pressure sensitive adhesive maintain fluid contact with the outer rigid layer. The outer layer may provide rigidity and sufficient abrasion resistance to external forces and impacts. Furthermore, shock absorbing layer may be porous and may be infused with the same or different pressure sensitive adhesive and has sufficient elasticity to allow the outer rigid layer to displace in response to a shear force there by not transmitting kinetic energy to the handheld device. Part of the outer rigid layer may be in direct contact or near direct contact with the device to alter the displacement characteristics, for example restrict dynamic motion towards a substantially delicate edges, boundaries, and/or corners.

In one embodiment, the protectors comprise a unique cross-sectional configuration, that resembles, such as, for example, a semi-cylinder, a semi-ellipse, an ovoid, that can be optimally adaptable to the specific region of the device to be applied.

Further, the protector and the shock absorbing elements may be formed to cover a substantially small portion of the handheld device that allows a user to access the surfaces and interactive controls of the handheld device. The shock absorbing material may be comprised of several layers with varied advantageous properties, such as compressive force and rebound time. The layers with varied characteristics along with the elastic properties of the adhesive may be adjusted to minimize impact force transmitted to the device without sufficiently increasing handheld device volume or weight by considering the drop height and weight of the specific handheld device.

An embodiment of the present invention may further comprise a shock absorbing element that has sufficient elasticity to reduce vibrational noise emitted by the handheld device.

An embodiment of the present invention may further comprise a method of protecting secondary attachments to the handheld device by attaching shock absorbing elements to the secondary device or the handheld device.

In one aspect, the disclosure provides an article of manufacture and a method for making an impact damage resistance protector for protecting a handheld device comprising, a clamshell, wherein the geometry of the clamshell is substantially a hollow prototype of the device to be protected, further wherein the clamshell contains features, such as cut-outs, that substantially align with the shock absorbing elements and predetermined locations on the handheld device. After attaching the shock absorbing elements at said predetermined locations the clamshell is removed and the fractionated protective cover is securely adapted to the desired region of interest on the intended device.

In another embodiment of the invention, the shock absorbing elements may be aligned and attached to the handheld device with magnetic fields and forces. For example, magnets may be added during the construction of the handheld device or the method outlined in paragraph [0013] may be used to adapt magnetic material elements to the handheld device.

In one aspect, the present disclosure provides an impact damage resistance protector system for protecting a device comprising: one or more shock absorbing element each comprising one or more shock absorbing pads adaptable on a boundary, edge, and/or corner of the device wherein the one or more shock absorbing elements are positioned to receive impacts which would otherwise strike the device.

In one aspect, the present disclosure provides an impact damage resistance protector for protecting a device comprising: a first shock absorbing element comprising one or more shock absorbing pads on a first corner of the device; a second shock absorbing element comprising one or more shock absorbing pads on a second corner of the device; a third shock absorbing element comprising one or more shock absorbing pads on a third corner of the device; a fourth shock absorbing element comprising one or more shock absorbing pads on a fourth corner of the device; wherein the first shock absorbing element, the second shock absorbing element, the third shock absorbing element, and the fourth shock absorbing element are positioned to receive impacts which would otherwise strike the device.

In one embodiment, the shock absorbing elements are located on substantially the boundaries, edges and/or corners of the device.

In one embodiment, the shock absorbing elements are located on substantially the boundaries, edges and/or corners of a secondary device attached to the device.

In one embodiment, the shock absorbing elements further comprise less than 5% of the area of the device.

In one embodiment, the shock absorbing elements comprise two or more shock absorbing pads.

In one embodiment, the shock absorbing element reduces vibrational noise emitted by the device.

In one aspect, the present disclosure provides an article of manufacture comprising material for withstanding high impacts comprising: a first layer; a second layer comprising; a first adhesive layer; a second shock absorbing membrane layer; and a third adhesive layer; wherein the first adhesive layer is a pressure sensitive adhesive that is in fluid contact with the second shock absorbing membrane layer, wherein the second shock absorbing membrane layer is infused with the same or different pressure sensitive adhesive and is in fluid contact with the third adhesive layer that is the same or different pressure sensitive adhesive; wherein the second shock absorbing membrane layer has elastic and energy absorbing mechanical properties; wherein the first layer is an energy absorbing and abrasive resistant material and is in direct contact with the second layer, further wherein the first and second layer are formed on a thermoset device to be protected.

In one embodiment, the material is placed on the boundaries, edges and/or corners of a device.

In one embodiment, the material is placed on the boundaries, edges and/or corners of the device and comprises less than 5% of the total area of the device allowing the first layer and the second layer to absorb energy, thus protecting the device from the high impact.

In one embodiment, the second layer further comprises elastic properties to allow the first layer to displace in response to a shear force.

In one aspect, the present disclosure provides an article of manufacture comprising material for withstanding high impacts comprising: a first edge; a second edge; a third edge; wherein the first edge is substantially at a right angle to the second edge and the first edge is substantially at a right angle to the third edge forming substantially a u-shape, further wherein the material encompasses substantially the boundaries, edges and/or corners of a device, further wherein the material comprises less than 5% of the device being covered.

In one aspect, the present disclosure provides a method for applying an impact damage resistance protector for protecting a device comprising: creating a clamshell of a device to be protected, where the clamshell comprises a first corner, a second corner, a third corner, and a fourth corner; encapsulating, or partially encapsulating the device, boundaries, edges, and/or corners a device to be protected with the clamshell; exposing wherein the geometry of the clamshell is substantially a hollow prototype of the device, boundaries, edges, and/or corners to be protected, further wherein the corners of the clamshell are substantially aligned with the impact damage resistance protector.

In one aspect, the present disclosure provides an article of manufacture comprising material for withstanding high impacts comprising: a first layer; a second shock absorbing membrane layer; a magnetic element; wherein the first layer is an energy absorbing and abrasion resistance material and is in direct contact with the second layer, wherein the second shock absorbing membrane layer has elastic and energy absorbing mechanical properties, further wherein the magnetic element is encapsulated by the first layer and provides a substantially magnetic field; wherein the magnetic field substantially engages the device and the second layer are formed on a device to be protected. In certain embodiments, part of the outer rigid layer may be in direct contact or near direct contact with the device to alter the displacement characteristics, for example restrict dynamic motion towards a substantially delicate edges, boundaries, and/or corners.

In one embodiment, the article can be packaged in a bi-fold configuration.

In one embodiment, the device is a handheld device.

In one embodiment, the device is a smartphone.

In one embodiment, the device is a tablet computer.

### BRIEF DESCRIPTION OF THE DRAWINGS

Various other objects, features, and attendant advantages of the present invention will be more fully appreciated from the following detailed description when considered in connection with the accompanying drawings in which like reference characters designate like or corresponding parts throughout the several views, and wherein:

FIG. 1 is a perspective view of an embodiment of the invention assembled on a handheld device.

FIG. 2 is a front view of an embodiment of the invention assembled on a handheld device.

FIG. 3 is a top view of an embodiment of the invention assembled on a handheld device.

FIG. 4 is a side view of an embodiment of the invention assembled on a handheld device.

FIG. 5 is a close-up section view of an embodiment of the invention shown in FIG. 4.

FIG. 6 is an exploded assembly diagram of an embodiment of the invention shown in FIG. 1.

FIG. 7 is an exploded perspective view of an embodiment of the assembly method of the invention.

FIG. 8 is a perspective view of another embodiment of the invention assembled on a handheld device.

FIG. 9 is a back view of another embodiment of the invention assembled on a handheld device.

FIG. 10 is a side view of another embodiment of the invention assembled on a handheld device.

FIG. 11 is a close-up section view of another embodiment of the invention shown in FIG. 10.

FIG. 12 is an exemplary embodiment of the impact damage resistant protector configured and operative according to the present disclosure.

FIG. 13 is an exemplary embodiment of the impact damage resistant protector configured and operative according to the present disclosure.

FIG. 14 is an exemplary embodiment of the impact damage resistant protector configured and operative according to the present disclosure.

FIG. 15 is an exemplary embodiment of the impact damage resistant protector configured and operative according to the present disclosure.

FIG. 16 is an exemplary embodiment of the impact damage resistant protector configured and operative according to the present disclosure.

FIG. 17 is an exemplary embodiment of the impact damage resistant protector configured and operative according to the present disclosure.

FIG. 18 is an exemplary embodiment of the impact damage resistant protector configured and operative according to the present disclosure.

FIG. 19 is an exemplary embodiment of the impact damage resistant protector configured and operative according to the present disclosure.

FIG. 20 is an exemplary embodiment of the impact damage resistant protector configured and operative according to the present disclosure.

FIG. 21 is an exemplary embodiment of the impact damage resistant protector configured and operative according to the present disclosure.

FIG. 22 is an exemplary embodiment of the impact damage resistant protector configured and operative according to the present disclosure.

FIG. 23 is an exemplary embodiment of the impact damage resistant protector configured and operative according to the present disclosure.

FIG. 24 is an exemplary embodiment of the impact damage resistant protector configured and operative according to the present disclosure.

FIG. 25 is an exemplary embodiment of the impact damage resistant protector configured and operative according to the present disclosure.

FIG. 26 is an exemplary embodiment of the impact damage resistant protector configured and operative according to the present disclosure.

FIG. 27 is an exemplary embodiment of the impact damage resistant protector configured and operative according to the present disclosure.

FIG. 28 is another view of the exemplary embodiment of the impact damage resistant protector configured and operative according to the present disclosure shown in FIG. 26.

FIG. 29 is an exemplary embodiment of the impact damage resistant protector configured and operative according to the present disclosure.

FIG. 30 is an exemplary embodiment of the impact damage resistant protector configured and operative according to the present disclosure.

FIG. 31 is an exemplary embodiment of the installation frame for guiding and placing the impact damage resistant protector configured and operative according to the present disclosure.

FIG. 32 is an exemplary embodiment of the installation frame for guiding and placing the impact damage resistant protector configured and operative according to the present disclosure.

FIG. 33 is an exemplary embodiment of the installation frame for guiding and placing the impact damage resistant protector configured and operative according to the present disclosure.

FIG. 34 is an exemplary embodiment of the installation frame for guiding and placing the impact damage resistant protector configured and operative according to the present disclosure.

FIG. 35 is an exemplary embodiment of the installation frame for guiding and placing the impact damage resistant protector configured and operative according to the present disclosure.

FIG. 36 is an exemplary embodiment of the installation frame for guiding and placing the impact damage resistant protector configured and operative according to the present disclosure.

FIG. 37 is an exemplary embodiment of the installation frame for guiding and placing the impact damage resistant protector configured and operative according to the present disclosure.

FIG. 38 is an exemplary embodiment of the installation frame for guiding and placing the impact damage resistant protector configured and operative according to the present disclosure.

FIG. 39 is an exemplary embodiment of the installation frame for guiding and placing the impact damage resistant protector configured and operative according to the present disclosure. The bi-fold configuration is shown.

FIG. 40 is an exemplary embodiment of the installation frame for guiding and placing the impact damage resistant protector configured and operative according to the present disclosure. The bi-fold configuration is shown.

FIG. 41 is an exemplary embodiment of the installation frame for guiding and placing the impact damage resistant protector configured and operative according to the present disclosure. The bi-fold configuration is shown.

FIG. 42 is an exemplary embodiment of the installation frame for guiding and placing the impact damage resistant protector configured and operative according to the present disclosure. Tablet version shown.

FIG. 43 is an exemplary embodiment of the installation frame for guiding and placing the impact damage resistant protector configured and operative according to the present disclosure. Tablet version shown.

FIG. 44 is an exemplary embodiment of the installation frame for guiding and placing the impact damage resistant protector configured and operative according to the present disclosure. Tablet version shown.

The following detailed description of embodiments of the invention refers to the accompanying drawings referred to above. Dimensions of components and features shown in the figures are chosen for convenience or clarity of presentation and are not necessarily shown to scale. Wherever possible, the same reference numbers will be used throughout the drawings and the following description to refer to the same and like parts.

### DETAILED DESCRIPTION

The present disclosure provides exemplary embodiment of the impact damage resistant protectors configured and operative according to the present disclosure. The protectors resemble a fractionated cover and provides impact protection for sensitive exemplary handheld devices.

In one embodiment, the protector comprises an outer wear resistant layer and a pressure sensitive adhesive which connect the shock absorbing elements further comprising a thin elastic membrane to the exemplary handheld device.

In one embodiment, the shock absorbing elements of the protector are adapted to the specific contour and profile of the device and allow the user to interact with the key-boards, push buttons, touch screens, and other interactive features of the device.

The protector, when adapted onto the device thereby resembling a fractionated device cover, is further adapted to allow the user to interact with a majority of the surfaces of the device.

Provided herein is an article of manufacture, comprising a thin enclosure adapted to the specific contours and profile of the exemplary handheld device, and further adapted to the profile of the shock absorbing protector elements that are temporarily placed over the handheld device corresponding to the exposed specific locations of the handheld device, to which the shock absorbing elements are integrally adapted thereon.

Accordingly, it can be perceived or appreciated that when the boundary, edge or corner protector is disposed around the boundary, edge or corner regions of an article, the internal surface portions of the shock absorbing adhesive elements will be disposed in surface-to-surface contact with the external side surface portions of the article. In one embodiment, the adhesive layer is separated and protected by a detachable membrane until use. In certain embodiments, said external corner edge protector has a cross-sectional configuration which can be shaped and similarly dimensioned as, for example, a semi-circle, a semi-ellipse, an ovaoid in accordance with the outer dimensions of the device to be attached thereto.

In another aspect, said impact damage protectors are designed with a minimal amount of materials and phone coverage.

an adhesive-infused membrane with an exoskeleton-like shell to safeguard highly probable damage locations as determined through an evaluation of the shape of the device and how it interacts with the geometry of the environment. This refined combination reduces stress on the entire device by redirecting impacts to larger surface areas and allows for motion of the outer-layer to dynamically absorb forces over a longer timeframe. As used herein, exemplary protector embodiments also elevate devices on all angles providing a protective gap for the device to lay down or be dragged against a flat surface minimizing damage to the device.

As used herein, exemplary devices suitably protected and configured and operative according to the embodiments of the present disclosure can include, but not limited to, calculators; dedicated e-book devices; digital media players; digital media displays e.g. portable DVD players; handheld game consoles; radio controlled toy e.g. RC transmitters; GPS Navigation Devices; wearable computer devices e.g. smart watches, headsup display glasses, wristband accelerometers; mobile handsets; e.g. cell phones, feature phones, smartphones; smartphone electronic accessories e.g. smartphone extended battery cases, wireless keyboards, portable speakers; voice tablets; tablet computers; notebook computers; external hard disk drives; digital cameras; e.g. action cameras, Digital Single Lens Reflex (SLR), compact cameras; mobile battery packs; and the like.

As used herein, the exemplary thermo plastic elastomers suitably configured and operative according to the embodiments of the present disclosure can include, but not limited to, thermoplastic olefin (TPO) e.g. ethylene propylene diene modified rubber (EPDM), ethylene propylene rubber (EPR), flexible polyolefin (FPO), polyolefin elastomer POE); styrenic block copolymer elastomers (SBC) e.g. SBS, SEBS, SIS; thermoplastic vulcanizate (TPV); thermoplastic polyurethanes (TPU) e.g. polyether-based, polyester-based, aromatic or aliphatic isocyanate; COPE—Polyether soft block segments coupled to aromatic polyester hard blocks; and PEBA—copolyamide type of elastomers.

As used herein, the exemplary thermo plastics suitably configured and operative according to the embodiments of the present disclosure can include, but not limited to, polybenzimidazole (PBI); polyoxymethylene (POM) e.g. acetal, polyacetal, polyformaldehyde, derlin; acrylonitrile butadiene styrene (ABS); aliphatic polyamides e.g. nylon; polycarbonate e.g. lexan; high-density polyethylene (HDPE); polyethylene high-density (PEHD); low-density polyethylene (LDPE); polymethyl methacrylate (Acrylic) e.g. Plexiglas; polystyrene (PS); polyetherimide (PEI); polyaryletherketone (PAEK) e.g. polyether ether ketone (PEEK), polyetherketoneketone (PEKK), polyether-ether-ketone-ketone (PEEKK), and polyetherketoneetherketoneketone (PEKEKK).

As used herein, the exemplary thermosetting resins suitably configured and operative according to the embodiments of the present disclosure can include, but not limited to, polyoxybenzylmethylenglycolanhydride; urea-formaldehyde e.g. plywood; melamine formaldehyde; polyepoxides epoxy resin; polymerized siloxanes or polysiloxanes; and vulcanized rubber.

As used herein, the exemplary composites suitably configured and operative according to the embodiments of the present disclosure can include, but not limited to, thermo plastic or thermo plastic elastomers composites with fillers, e.g. glass bead, glass fiber, miller glass fiber, calcium carbonate, talc, hollow silicate sphere; carbon-fiber-reinforced polymer, e.g. carbon-fiber reinforced thermoplastic (CFRP, CRP, CFRTP), para-aramid synthetic fiber reinforced thermoplastic; composite wood e.g. wood laminates; resins and wood composites e.g. bamboo, maple, cherry, zebra, koa, walnut, mahagony, redwood, ash, beach, cedar, pine, coconut, cork, oak, hickory, acacia, cypress, birch, rosewood, bloodwood, chestnut, teak, cumaru, elm, and hevea.

In other embodiments, the protector material can comprise both magnetic and non-magnetic metallic elements for structural rigidity and/or aesthetic purposes.

As used herein, the exemplary metals suitably configured and operative according to the embodiments of the present disclosure can include, but not limited to, aluminum alloys e.g. 1100, 2007, 2011, 2017, 2024, 3003, 4032, 5005, 5052, 5083, 5086, 5205, 6013, 6020, 6060, 6061, 6063, 7050, 7068, 7075; stainless steel e.g. 316, 303, 304, 430; titanium; gold, platinum, copper alloys e.g. 101, 110, 122, 182, 145, 145; brass alloys e.g. 260, 330, 353, 360, 385, 485; bronze e.g. 220, 510, 316, 544, 544, 642, 655, 932, 936, 954, SAE 841, and metal composites, e.g. sintered stainless steel infused with bronze.

As used herein, outer material can be selected based on hardness, stiffness and other mechanical properties to be correlated to targeted drop height. Target height range can drastically be altered with different shock absorbing materials and adhesive selections. Upon substantially high impact loads materials elastically (temporary) or in some cases plastically (permanent) deform, reducing and redistributing the forces transmitted to the phone. The following hardness correlates to ideal drop height protection, shore 80D+ for ideal range of 3+ ft, shore 55-80 for ideal range of 18″-8 ft, shore 20-50 for ideal rang of 4″-24″, 1/16-¼″ shock absorbing membrane for ideal range of 0-6″ which also provides sound dampening from vibration, but is not abrasion resistant.

As used herein, the exemplary coatings suitably configured and operative according to the embodiments of the present disclosure can include, but not limited to, rubber coating; silicone coating e.g. for texture and surface grip, lamination of decorative nature which may be applied and expected to be sacrificial and therefore use a substantially lower strength adhesive to facilitate the more frequent application and removal.

As used herein, the exemplary shock absorbing membrane suitably configured and operative according to the protector embodiments of the present disclosure can include, but not limited to, closed cell acrylic; closed cell polyurethane; rubber. Thickness of the shock absorbing membrane correlates to optimal drop protection height, e.g. substantially thin in a range 0.24-0.64 mm and 800 k/m̂3 density shock absorbing membranes allow optimal outer layer movement for higher impacts of 12″+, substantially thick in the range of 0.64-1.1+ mm and 590-720 k/m̂3 density shock absorbing membrane provide optimal cushioning for drops 12″ and less.

Through the shock absorbing membrane construction, the dynamic motion of the outer shell of the protector can be altered by using shock absorbing membrane with anisotropic properties, e.g. fibers added to the shock absorbing membrane in the x-y direction reduce motion of the outer shell due to a shear force in the x-y direction compared to shock absorbing membrane with no fiber. The current example of increasing the shear resistance would reduce motion caused by forces orthogonal to the screen. This enables a higher ideal drop protection height with the same outer shell protrusion, or the same ideal drop protection height with a lower protrusion of the outer shell.

As used herein, the exemplary adhesive bond strength suitably configured and operative according to the embodiments of the present disclosure can include, but not limited to, an adhesive bond strength selected to join the shock absorbing membrane, outer shell and device. Energy during an abnormally high impact is transmitted to the partial separation of the cohesion forces through partial peeling of the adhesive. As used herein, the exemplary adhesives suitably configured and operative according to the embodiments of the present disclosure can include, but not limited to, acrylic; modified acrylic; rubber; pressure sensitive adhesive; e.g. 90 degree peel adhesion of 300 N/100 mm to 440 N/100 mm, normal tensile 380-1100 kPa to ensure proper attachment is maintained to the device while still allowing for hand removal; adhesive capable of withstanding a dynamic shear of 550 kPa that will maintain connection with materials with a substantially high durometer outer shell; adhesive capable of withstanding a dynamic shear of 690 kPa is required for an outer layer with a durometer that is substantially low.

As used herein, the exemplary adhesive promoter suitably configured and operative according to the protector embodiments of the present disclosure can include, but not limited to, cyclohexane (110-82-7); xylene (1330-20-7); ethyl alcohol (64-17-5); ethylbenzene (100-41-4); ethyl acetate (141-78-6); acrylic polymer (NJST#044996005984P); chlorinated polyethlene (68609-36-9). An adhesive primer may be required to promote the proper adhesion of the adhesive to the outer shell for substantially low surface energy materials, e.g. polyethylene, polypropylene, ABS, PET/PBT blends, concrete, wood, glass, metal and painted surfaces.

In one aspect, the disclosure provides an article of manufacture and a method for installing protectors for exemplary devices comprising, a clamshell, wherein the geometry of the clamshell is substantially a hollow prototype of the device to be protected, further wherein the clamshell contains features, such as cut-outs, that substantially align with the shock absorbing elements and predetermined locations on the handheld device. After attaching the shock absorbing elements at said predetermined locations the clamshell is removed and the fractionated protective cover is securely adapted to the desired region of interest on the intended device.

In one embodiment, the protector packaging and installation frame substantially protects the products through a substantial or partial portion of the retail distribution channel.

In one embodiment, the protector there are substantial physical contact points between the product and package in combination with substantial physical contact points with the device (to have the product installed) and the package allow for proper alignment of the product to the device.

Protector Elements and Suitable Materials

As used herein, (cellulose pulp products) suitably configured and operative according to the protector embodiments of the present disclosure can include, but not limited to, paper products e.g. Chip board, Solid Bleached Board, Solid Bleached Sulphate, Molded Pulp; Compress fibers, e.g. plant or synthetic based; paper and plastic laminate; and the like.

As used herein, thermoform film plastics suitably configured and operative according to the protector embodiments of the present disclosure can include, but not limited to, Polystyrene (PS), Polypropylene (PP), polycarbonate (PC), polyester, polyvinyl chloride (PVC), Polyethylene terephthalate (PET, PETE), Acrylonitrile butadiene styrene (ABS), Thermoplastic Polyurethane, High-density polyethylene (HDPE), polyethylene high-density (PEHD), Low-density polyethylene (LDPE), and Polymethyl methacrylate(Acrylic); and the like.

As used herein, formed metals suitably configured and operative according to the protector embodiments of the present disclosure can include, but not limited to, Aluminum alloys; e.g. 1100, 2007, 2011, 2017, 2024, 3003, 4032, 5005, 5052, 5083, 5086, 5205, 6013, 6020, 6060, 6061, 6063, 7050, 7068, 7075; Stainless steel; e.g. 316, 303, 304, 430; Brass Alloys; e.g. 260, 330, Bronze; 220, 510, 316, 544; and the like.

As a result of the aforementioned structure characteristic of the new and improved boundary, edge or corner protector as disclosed herein, certain unique and novel operational features and structural characteristics are effectively implemented.

In one embodiment, the exemplary protectors protects the screen without impeding access by the user. As such, the exemplary impact damage protectors allow for screen protectors to be installed before or after the installation said impact damage protectors

In one embodiment, the exemplary protectors will not cause the screen protector to lift and become visible.

In one embodiment, the exemplary protectors will allow for dynamic motion of the product force and, therefore forces are transmitted to the device in a short amount of time cause high stresses.

In one embodiment, the exemplary protectors leave a minimalist footprint on the device and thereby prevents interference with many form fitted products and typical user locations, such as pockets and hand bags.

In one embodiment, the exemplary protectors keep the product attached to the device during a drop over 3 ft.

In one embodiment, the exemplary protectors are concave front and back.

In one embodiment, the exemplary protectors provide protection on all sides of the device.

In one embodiment, the exemplary protectors do not cover the device screen and results in directing the forces generated during an impact to be transmitted to the screen increasing risk of damage.

FIG. 1 shows a perspective view of one protector embodiment of the invention assembled on a handheld device. The fractionated protector includes a first shock absorbing element 100, a second shock absorbing element 101, a third shock absorbing element 102, and a fourth shock absorbing element 103. When assembled shock absorbing elements are positioned to receive impacts which would otherwise strike the handheld device 104. Handheld device 104 can be any type of device that requires interactivity with a user of the device including MP3 players, video players, computers, smart phones, walkie talkies, monitors, tablet computers, and other handheld devices. FIG. 2, FIG. 3, and FIG. 4 shows a front view, top view, and side view, respectively, of an embodiment of the invention assembled on a handheld device. In all three views the shock absorbing elements, 100, 101, 102, and 103, extend past the outer perimeter of the device on the order or 0.8 mm to 2.0 mm. During an impact with a substantially large flat surface, the shock absorbing elements make contact with said surface which protects the device from an impact. A secondary case or cover may encapsulate the fractionated protector to add additional functionality such as dust resistance or water resistance.

FIG. 5 shows a detailed section view of the shock absorbing element 100. The shock absorbing and abrasion resistant outer layer 1000, can be made from a soft plastic, such as polycarbonate, nylon, PVC, urethane, silicone or metal material that can be molded, such as by thermo forming, casting, stretching, heating, or injection molding, machining, or otherwise shaped to fit the edges, corners or other surfaces of the device 104. The geometric features of the shock absorbing and abrasion resistant outer layer 1000 substantially align with the geometric features of the device 104 to provide attachment at a predetermined location. The shock absorbing layer 1005 may be made from a single material or multiple materials that are combine to form a layered structure or single layer. For example, the shock absorbing layer 1005 may be made of a thin polyurethane shock absorbing membrane on the order of 0.025 to 0.062 inches, infused with pressure sensitive adhesive. The shock absorbing layer 1005 compresses and changes the momentum of the device over a longer distance and thus reduces the impact force experienced by the device. Placement of the material on the electronic device is important to the correct functioning of the method described in this document. The shock absorbing element 100 is shaped in a way to provide substantially large surface area between the electronic device and the accidental contact surface on sections of the device 104 that are most likely to make independent contact with the accidental contact surface, such as the corners and edges of the electronic device 104. Further, the shock absorbing element 100 is shaped to provide smaller contact surface areas for sections of the device 104 that are most probable to result in simultaneous contact with the accidental contact surface, such as the front the device 104. Correlating the geometry 1006 of the shock absorbing element 100 to the geometry 1006 of the device 104 and the accidental drop characteristics allows shock absorbing element 100 to be of substantially small in size and weight.

FIG. 6 shows an exploded view of one embodiment of a protective fractionated cover. The protective fractionated cover includes a first abrasion resistant outer layer 1000, a first shock absorbing layer 1005, a second abrasion resistant outer layer 1001, a second shock absorbing layer 1002, a third abrasion resistant outer layer 1003, a third shock absorbing layer 1006, a fourth abrasion resistant outer layer 1004, a fourth shock absorbing layer 1007.

FIG. 7 shows an embodiment of making a impact damage resistance protector for protecting a handheld device 104 comprising, a clamshell 109, wherein the geometry of the clamshell is substantially a hollow prototype of the device to be protected, further wherein the clamshell contains features, such as cutouts, that substantially align with the shock absorbing elements 100, 101, 102, 103. The clamshell is place around the device 104 and the cutouts in the clamshell 109 expose predetermined locations on the handheld device 104. The geometric features of the clamshell 109 contact the shock absorbing element 100 and guide the attachment of the element 100 to be formed on the predetermined location. The clamshell 109 is then removed leaving on the fractionated protective cover. The clamshell 109 may be made from soft plastic, such as polycarbonate, PVC, polypropylene, paper, cardboard, or other plastics and paper materials that can be molded, such as by thermo forming, casting, stretching, heating, or injection molding, or otherwise shaped to fit the contours or other surfaces of the device 104.

FIG. 8 shows a perspective view of another embodiment of the invention assembled on a tablet computer device. The fractionated protective cover includes a first shock absorbing element 110, a second shock absorbing element 111, a third shock absorbing element 112, and a fourth shock absorbing element 113. When assembled shock absorbing elements are positioned to receive impacts which would otherwise strike the tablet computer device 114.

FIG. 9 and FIG. 10 shows a back view and side view, respectively, of another embodiment of the invention as shown in FIG. 8. In both views the shock absorbing elements, 110, 111, 112, and 113, extend past the outer perimeter of the tablet computer 114 on the order or 0.8 mm to 2.0 mm. During an impact with a substantially large flat surface, the shock absorbing elements make contact with said surface which protects the device from an impact.

FIG. 11 shows a detailed section view of the shock absorbing element 110. The shock absorbing and abrasion resistant outer layer 1110, can be made from a soft plastic, such as polycarbonate, nylon, PVC, urethane, silicone or metal material that can be molded, such as by thermo forming, casting, stretching, heating, or injection molding, machining, or otherwise shaped to fit the edges, corners or other surfaces of the device 114. The geometric features of the shock absorbing and abrasion resistant outer layer 1000 substantially align with the geometric features 1160 of the device 114 to provide attachment at a predetermined locations. The shock absorbing layer 1150 may be made from a single material or multiple materials that are combine to form a layered structure or single layer. For example, the shock absorbing layer 1150 may be made of a thin polyurethane shock absorbing membrane on the order of 0.045 to 0.062 inches, infused with pressure sensitive adhesive.

Further exemplars of the boundary, edge or corner impact damage resistant protector as disclosed herein are further illustrated in the accompanying Figures.

Thus, it may be seen that in accordance with the principles and teachings of the present invention, there has been provided a new and improved boundary, edge or corner impact damage resistant protector which are adapted to be disposed around the external boundary, corner or edge region of an article.

What is claimed is:

1. An impact damage resistance protector system for protecting a device comprising:
one or more shock absorbing element each comprising one or more shock absorbing pads adaptable on a boundary, edge, and/or corner of the device wherein the one or more shock absorbing elements are positioned to receive impacts which would otherwise strike the device.

2. The impact damage resistance protector of claim 1, wherein the shock absorbing elements are located on substantially the boundaries, edges and/or corners of the device.

3. The impact damage resistance protector of claim 1, wherein the shock absorbing elements are located on substantially the boundaries, edges and/or corners of a secondary device attached to the device.

4. The impact damage resistance protector of claim 1, wherein the shock absorbing elements further comprise less than 5% of the area of the device.

5. The impact damage resistance protector of claim 1, wherein the shock absorbing elements comprise two or more shock absorbing pads.

6. The impact damage resistance protector of claim 1, wherein the shock absorbing element reduces vibrational noise emitted by the device.

7. An article of manufacture comprising material for withstanding high impacts comprising:
a first layer;
a second layer comprising; a first adhesive layer;
a second shock absorbing membrane layer; and a third adhesive layer;
wherein the first adhesive layer is a pressure sensitive adhesive that is in fluid contact with the second shock absorbing membrane layer, wherein the second shock absorbing membrane layer is infused with the same or different pressure sensitive adhesive and is in fluid contact with the third adhesive layer that is the same or different pressure sensitive adhesive;
wherein the second shock absorbing membrane layer has elastic and energy absorbing mechanical properties; and
wherein the first layer is an energy absorbing and abrasive resistant material and is in direct contact with the second layer, further wherein the first and second layer are formed on a device to be protected.

8. The material of claim 7, wherein the material is placed on the boundaries, edges and/or corners of a device.

9. The material of claim 8, wherein the material is placed on the boundaries, edges and/or corners of the device and comprises substantially less than the total area of the device allowing the first layer and the second layer to absorb energy, thus protecting the device from the high impact.

10. The material of claim 9, wherein the second layer further comprises elastic properties to allow the first layer to displace in response to a shear force.

11. An article of manufacture comprising material for withstanding high impacts comprising:
a first edge; a second edge; a third edge;
wherein the first edge is substantially at a right angle to the second edge and the first edge is substantially at a right angle to the third edge forming substantially a u-shape, further wherein the material encompasses substantially the boundaries, edges and/or corners of a device, further wherein the material comprises less than 5% of the device being covered.

12. A method for applying an impact damage resistance protector for protecting a device comprising:
creating a clamshell of a device to be protected, where the clamshell comprises a first corner, a second corner, a third corner, and a fourth corner; encapsulating, or partially encapsulating the device, boundaries, edges, and/or corners a device to be protected with the clamshell; exposing
wherein the geometry of the clamshell is substantially a hollow prototype of the device, boundaries, edges, and/or corners to be protected, further wherein the corners of the clamshell are substantially aligned with the impact damage resistance protector.

13. An article of manufacture comprising material for withstanding high impacts comprising:
a first layer;
a second shock absorbing membrane layer
a magnetic element
wherein the first layer is an energy absorbing and abrasion resistance material and is in direct contact with the second layer, wherein the second shock absorbing membrane layer has elastic and energy absorbing mechanical properties, further wherein the magnetic element is encapsulated by the first layer and provides a substantially magnetic field.
wherein the magnetic field substantially engages the device and the second layer are formed on a device to be protected.

14. The article of manufacture according to claim 11 wherein the article can be packaged in a bi-fold configuration.

15. The impact damage resistance protector of claims 1-3 wherein the device is a handheld device.

16. The device of claim 15 wherein the device is a smartphone.

17. The impact damage resistance protector of claims 1-3 wherein the device is a tablet computer.

18. An impact damage resistance protector system for protecting a device comprising:
a first shock absorbing element comprising one or more shock absorbing pads on a first corner of the device;
a second shock absorbing element comprising one or more shock absorbing pads on a second corner of the device;
a third shock absorbing element comprising one or more shock absorbing pads on a third corner of the device;
a fourth shock absorbing element comprising one or more shock absorbing pads on a fourth corner of the device;
wherein one or more shock absorbing elements are positioned to receive impacts which would otherwise strike the device.
